(19) United States
(12) Patent Application Publication
(10) Pub. No.: US 2007/0251819 A1
(43) Pub. Date: Nov. 1, 2007

(54) Hollow cathode magnetron sputtering targets and methods of forming hollow cathode magnetron sputtering targets

(76) Inventors: Janine K. Kardokus, Veradale, WA (US); Susan D. Strothers, Spokane, WA (US); Sally A. Woodward, Liberty Lake, WA (US); Stephane Ferrasse, Veradale, WA (US)

Correspondence Address: WELLS ST. JOHN P.S., 601 W. FIRST AVENUE, SUITE 1300, SPOKANE, WA, 99201, US

(21) Appl. No.: 11/415,620

(22) Filed: May 1, 2006

(51) Int. Cl. C23C 14/00

(52) U.S. Cl. 204/298.13

(57) ABSTRACT

The invention includes methods of forming hollow cathode magnetron sputtering targets. A metallic material is processed to produce an average grain size of less than or equal to about 30 microns and subsequently subjected to deep drawing. The invention includes three-dimensional sputtering targets comprising materials containing at least one element selected from Cu, Ti, and Ta. The target has an average grain size of from about 0.2 microns to about 30 microns throughout the target and a grain size standard deviation of less than or equal to 15% (1-σ). The invention includes three-dimensional targets comprising Al, having an average grain size of from 0.2 microns to less than 150 micron, with a grain size standard deviation of less than or equal to 15% (1-σ).

### TECHNICAL FIELD

The invention pertains to three-dimensional physical vapor deposition (PVD) targets such as, for example, hollow cathode magnetron targets, and methods of forming three-dimensional PVD.

### BACKGROUND OF THE INVENTION

Physical vapor deposition (PVD) is commonly used for forming thin layers of material in processes such as semiconductor fabrication. PVD includes sputtering processes. In an exemplary PVD process a cathodic target is exposed to a beam of high-intensity particles. As the high-intensity particles impact a surface of the target, they force materials to be ejected from the target surface. The materials can then deposit onto a semiconductor substrate to form a thin film of the materials across a substrate.

Difficulties are encountered during PVD processes in attempting to obtain a uniform thickness across a semiconductor substrate surface, particularly where the substrate surface comprises various topological features and/or complex geometric features. Attempts have been made to address such difficulties with target geometry. Accordingly, numerous target geometries are currently being commercially produced. Exemplary geometries are described generally with reference to FIGS. 1-4. FIGS. 1 and 2 illustrate an isometric and cross-sectional sideview, respectively, of a flat target construction 16. FIGS. 3 and 4 illustrate an isometric view and cross-sectional sideview, respectively, of an exemplary three-dimensional target construction.

Each of the cross-sectional sideviews of FIGS. 2 and 4 is shown comprising horizontal dimensions “x” and vertical dimensions “y”. The ratio of y to x can determine or define whether the target is a so called three-dimensional target or a two-dimensional target. Specifically, each of the illustrated targets comprises a horizontal dimension x of from about 13 inches to about 22 inches. The flat target illustrated in FIG. 2 will typically comprise a vertical dimension of less than or equal to about 1 inch. The three dimensional target illustrated in FIG. 4 will typically comprise a vertical dimension of from about 2 to about 10 inches. For purposes of interpreting this disclosure and the claims that follow, a target is considered to be a three-dimensional target if the target has a more complicated shape than the simple planar target of FIG. 2, and in particular aspects a three-dimensional target can be a target in which the ratio of the vertical dimension y to the horizontal dimension x is greater than or equal to 0.15. In particular aspects of the present invention a three-dimensional target can have a ratio of the vertical dimension y to the horizontal dimension x of greater than or equal to 0.5. If the ratio of the vertical dimension y to the horizontal dimension x is less than 0.15, the target is considered to be a two-dimensional target.

The exemplary target depicted in FIG. 4 can be considered to comprise a complex three-dimensional geometry in that it can be difficult to fabricate monolithic targets having geometry similar to that depicted. The exemplary three-dimensional target has geometrical characteristics comprising a cup 11 having a pair of opposing ends 13 and 15. End 15 is opened and end 13 is closed. The cup 11 has a hollow 19 extending therein. Further, cup 11 has an internal (or interior) surface 21 defining a periphery of hollow 19, and an exterior surface 23 in opposing relation to the interior surface. Exterior surface 23 extends around cup 11, around closed-end 13, and around radius 25. Target 12 has a sidewall 27. For purposes of the present description the term “sidewall” is utilized to refer to vertical portions 27 bounded by interior surface 21 and exterior surface 23 defined by the exterior and interior surfaces. The term base portion can be used to refer to horizontal (as depicted) portion 24 extending between radius 25 and bounded by interior surface 21 and exterior surface 23. Rather than having sharp corners at the junction of the base and the sidewall, the three dimensional target configuration can typically have radius portion 25 which is sloped, angled, or curved, and extends between the horizontal base and vertical sidewalls. Sidewalls 27 extend vertically from radius 25 to end 15.

Target 12 depicted in FIG. 4 further comprises a flange 29 extending laterally outward around the sidewall 27 proximate end 15. In alternative configurations, flange 15 can be absent from the target structure (not shown).

The exemplary target 12 depicted in FIG. 4 can be utilized in hollow cathode magnetron (HCM) sputtering systems. Accordingly, target 12 can be referred to as a hollow cathode magnetron (HCM) target. Advantages of utilizing three-dimensional targets such as HCM targets in physical vapor deposition processes, as opposed to utilizing two-dimensional or planar targets can include uniformity of deposition. However, conventional three-dimensional targets are still pressed to meet the ever increasing uniformity requirements for semiconductor manufacturing purposes. Precision in film thickness and uniformity is increasingly important as the density of semiconductor devices on a given surface area of a semiconductor wafer increases. Further, conventional targets including conventional three-dimensional targets are often limited in the area over which film uniformity of thickness and quality can be maintained such that uniformity requirements for large semiconductor wafers (such as 300 mm wafers) are not satisfied. Accordingly, it would be desirable to develop alternative three-dimensional targets capable of improved uniformity of deposition across larger surface areas.

### SUMMARY OF THE INVENTION

In one aspect, the invention encompasses a method of forming a hollow cathode magnetron sputtering target. A metallic material is processed to produce an average grain size of less than or equal to about 20 microns. The material is then subjected to deep drawing.

In one aspect the invention encompasses a three-dimensional sputtering target comprising a metallic material containing at least one element selected from Cu, Ti, and Ta. The target has an average grain size of from about 0.2 microns to about 30 microns throughout the target. The target has a grain size standard deviation throughout the target of less than or equal to 15% (1-σ).

In one aspect the invention encompasses a three-dimensional aluminum or doped aluminum target having an average grain size of less than 150 micron and a grain size standard deviation throughout the target of less than or equal to 15% (1-σ). Alternatively, the three dimensional target can comprise an aluminum alloy and can have an average grain size of from 0.2 microns to about 30 microns, with a grain size standard deviation throughout the target of less than or equal to 15% (1σ)

### BRIEF DESCRIPTION OF THE DRAWINGS

Preferred embodiments of the invention are described below with reference to the following accompanying drawings.

FIG. 1 is an isometric view of a prior art flat sputtering target.

FIG. 2 is a cross-sectional sideview of the FIG. 1 sputtering target.

FIG. 3 is an isometric view of an exemplary hollow cathode sputtering target.

FIG. 4 is a cross-sectional sideview of the FIG. 3 sputtering target.

FIG. 5 is a diagrammatic cross-sectional view of a physical vapor deposition system and shows a physical vapor deposition target construction proximate a substrate.

FIG. 6 is a diagrammatic cross-sectional view of a material being treated with an equal channel angular extrusion apparatus.

FIG. 7 is a diagrammatic cross-sectional sideview of a deep drawn target illustrating target areas for material analysis purposes.

FIG. 8 shows a 400× enlargement of microstructure of a deep drawn target formed utilizing equal channel angular extrusion copper material prior to deep drawing. Such material has been processed utilizing equal channel angular extrusion (6 passes through route D) and 70% reduction by rolling, followed by annealing at 235° C. for 1 hour. The micrograph shows a sample taken from the top (base) of the deep drawn target.

FIG. 9 shows the microstructure (at 400× magnification) of a planar section from the side of the deep drawn target shown in FIG.8.

FIG. 10 shows a 400× magnification of a cross-section of the top of a deep drawn target after annealing at 225° C. for 1 hour.

FIG. 11 shows a 400× magnification of a cross-section taken from the side of a deep drawn target after annealing at 225° C. for 1 hour.

FIG. 12 shows a graph illustrating the effect of annealing on grain size for deep drawn high-purity copper material containing 2.0-2.5 ppm Ag.

FIG. 13 shows a planar section of a sidewall at 200× magnification of a deep drawn target after annealing at 300° C. for 1 hour. The average grain size of the material prior to deep drawing was 0.5 microns.

FIG. 14 shows a planar section of a sidewall of a deep drawn target after annealing at 300° C. for 1 hour (200× magnifications). The average grain size of the material prior to deep drawing was 10 microns.

FIG. 15 shows the grain size uniformity determined for a 6N copper deep drawn target formed in accordance with the invention.

FIG. 16 shows an optical-micrograph-of a cross-section taken from a deep-drawn aluminum alloy structure.

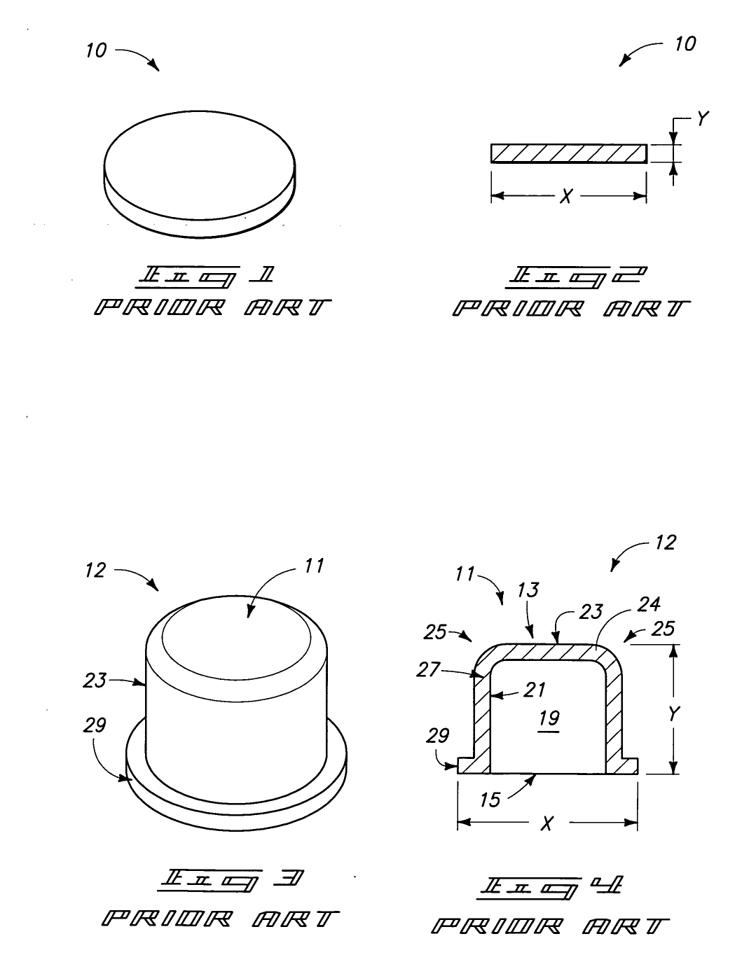

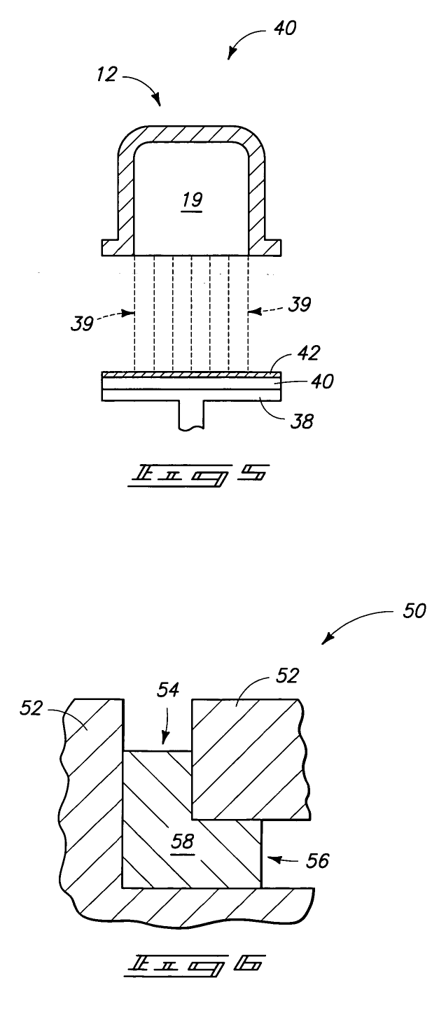

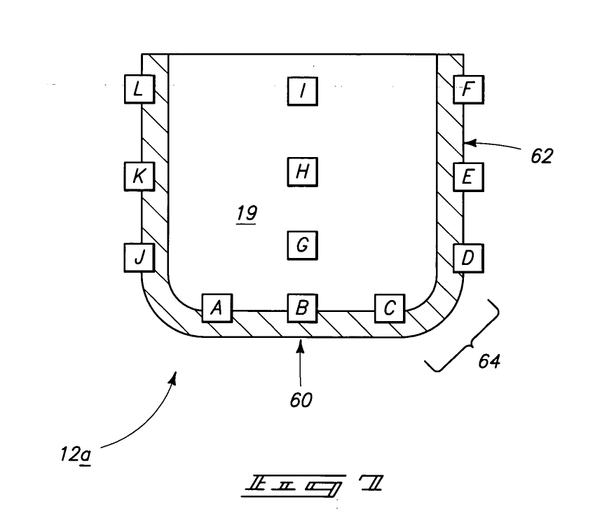

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

In general the invention pertains to production and use of three dimensional targets such as hollow cathode magnetron (HCM) targets capable of production of films having improved film uniformity relative to conventional HCM targets. In particular, the HCM targets of the invention are produced to have fine grain size, grain size uniformity and grain size stability. For ease of description, the invention is described with reference to an HCM target. However, it is to be understood that the described methodology, materials and structures can be equally applicable to alternative three-dimensional target configurations such as described above.

Referring to FIG. 5 an exemplary HCM system 40 is shown diagrammatically illustrating a physical vapor deposition process utilizing an exemplary HCM target 12, which can be a target in accordance with the invention. A substrate 40 is positioned proximate the HCM physical vapor deposition target 12 (also referred to as a sputtering target). Substrate 40 can be positioned on a holder 38 and can optionally be biased.

During a sputtering process, substrate 40 is typically placed at a defined distance opposite hollow portion 19 of target 12 which is mounted within the sputtering apparatus (not shown). During a sputtering process a high-density plasma is utilized to sputter and ionize target material within hollow interior 19. In the HCM system, magnetic fields are utilized to direct ions substantially perpendicular relative to the surface of substrate 40 as depicted by lines 39 in FIG. 5. The ejected ions are deposited to form a thin film or layer 42 on the surface of substrate 40.

Due to the extreme high density of plasma (typically at least 10¹³ ions/cm³) utilized in HCM sputtering systems, it has not been previously predicted that grain size of the sputtering target material could substantially influence film uniformity. Accordingly, conventional HCM targets are typically produced which have large grain sizes. For copper materials, such grain sizes are typically on the order of greater than or equal to 50 microns. Conventional production of HCM targets of alternative metal materials similarly results in relatively large grains for the particular material being processed. Conventional HCM targets production methodology additionally does not particularly focus on or achieve a uniform grain size across target surfaces, target areas, or throughout the entire target.

Although in particular instances and for certain materials, conventional HCM targets were capable of improving thin film uniformity relative to alternative target configurations (such as planar targets), targets in accordance with the invention have improved grain size uniformity, decreased average grain size, and show consistent and marked improvement in resulting thin film uniformity. The improvement is most notable for high-purity materials and especially ultra high purity materials (having a metallic purity of 99.9999% or higher).

For purposes of the present description, with respect to high-purity non-alloy materials, the term “metallic purity” refers to the amount or percent by weight of the metal material (excluding gases) which consists of the particular metal element. For example, a 99.9999% pure copper material refers to a metal material where 99.9999% of the total metal content by weight is copper atoms. With respect to an alloy or a doped material, the purity level specified indicates the purity of the base metal prior to addition of any alloying or doping elements.

Although the methodology and targets of the invention can utilize metallic materials having a decreased purity, the methodology and targets produced in accordance with the invention can be particularly advantageous where ultra high-purity materials are to be deposited (purity of 99.9999% or higher) since achieving uniformity of films of high-purity materials is especially difficult. Of particular interest for HCM targets in accordance with the invention are high-purity copper, aluminum, titanium or tantalum and their alloys.

Methodology and targets produced in accordance with the invention can also be useful for production of lower purity copper (or alternative metal) materials such as, for example, copper having a purity of at least 99.99% copper, by weight.

Copper alloys can also be utilized such as, for example, alloys containing 99.999% pure base-copper to which has been added at least one alloying element selected from the group consisting of Cd, Ca, Au, Ag, Be, Li, Mg, Al, Pd, Hg, Ni, In, Zn, B, Ga, Mn, Sn, Ge, W, Cr, O, Sb, Ir, P, As, Co, Te, Fe, S, Ti, Zr, Sc, Si, Pt, Nb, Re, Mo, and Hf. The term “alloy” as used herein refers to a target material containing a base metal to which at least about 100 ppm of alloying element(s) has been added. In particular instances copper alloys can preferably contain one or more elements selected from Ag, Mg, Al, In, Sn, P and Ti. A preferred total content range for these alloying elements can be from about 100 ppm to about 2 percent, by weight.

Target materials and targets in accordance with the invention also include doped materials having a high percentage of a particular metal such as copper and additionally containing at least one doping element. For purposes of the present description, a doped material refers to a material having a base metal (preferably high-purity) to which less than or equal to 100 ppm of doping elements have been added. Where the doped material is a copper material, the material can preferably contain 99.9999% copper to which one or more doping element has been added. The doping elements for copper materials can preferably include at least one doping element selected from the group consisting of Cd, Ca, Au, Ag, Be, Li, Mg, Al, Pd, Hg, Ni, In, Zn, B, Ga, Mn, Sn, Ge, W, Cr, O, Sb, Ir, P, As, Co, Te, Fe, S, Ti, Zr, Sc, Si, Pt, Nb, Re, Mo, and Hf. Ag can be a preferred doping element for HCM targets of the invention comprising doped copper materials.

Alternative doped metallic materials can be doped aluminum materials. Doped-aluminum targets of the invention preferably contain at least about 99.99% aluminum, by weight, and additionally contain at least one doping element selected from the group consisting of Cu, Cd, Ca, Au, Ag, Be, Li, Mg, Pd, Hg, Ni, In, Zn, B, Ga, Mn, Sn, Ge, W, Cr, O, Sb, Ir, P, As, Co, Te, Fe, S, Ti, Zr, Sc, Si, Pt, Nb, Re, Mo, and Hf. Doped aluminum targets in accordance with the invention preferably have a total dopant content of at least 1 ppm. In particular application, doping elements can preferably include one or more of Ti, Sc and Si.

HCM targets of the invention can alternatively be aluminum alloy targets. For aluminum alloy targets, the target material preferably contains aluminum having a purity 99.99% aluminum, by weight to which one or more alloying element has been added. The aluminum alloy targets can include at least one alloying element selected from Cu, Cd, Ca, Au, Ag, Be, Li, Mg, Pd, Hg, Ni, In, Zn, B, Ga, Mn, Sn, Ge, W, Cr, O, Sb, Ir, P, As, Co, Te, Fe, S, Ti, Zr, Sc, Si, Pt, Nb, Re, Mo, and Hf, with a total amount of alloying elements being at least 100 ppm. In particular applications, the alloying elements utilized will include at least one of Cu, Ti and Si.

Titanium alloy and tantalum alloy targets in accordance with the invention will preferably contain either Ti or Ta of 99.9% or greater purity, by weight, to which has been added at least one alloying element selected from the group consisting of Cu, Cd, Ca, Au, Ag, Be, Li, Mg, Pd, Hg, Ni, In, Zn, B, Ga, Mn, Sn, Ge, W, Cr, O, Sb, Ir, P, As, Co, Te, Fe, S, Ti, Zr, Sc, Si, Pt, Nb, Re, Mo, and Hf.

Alternative HCM targets in accordance with the invention can contain doped Ti or Ta materials. Such doped materials preferably contain Ti or Ta having a purity of greater than or equal to 99.9%, to which has been added at least one doping element selected from the group consisting of Cu, Cd, Ca, Au, Ag, Be, Li, Mg, Pd, Hg, Ni, In, Zn, B, Ga, Mn, Sn, Ge, W, Cr, O, Sb, Ir, P, As, Co, Te, Fe, S, Ti, Zr, Sc, Si, Pt, Nb, Re, Mo, and Hf. A total amount of doping elements present in the Ta or Ti target can preferably be from about 1 to about 100 ppm.

Three dimensional targets of the invention can have any three-dimensional shape, such as conventional target shapes including but not limited to HCM target shapes, and alternative 3 dimensional shapes described above (see background section). Accordingly, conventional sputtering systems, especially those developed for utilization of three-dimensional targets can be utilized for depositing materials from targets of the invention. HCM targets of the invention can be described as comprising a base portion, a radius, and a sidewall portion, as set forth above.

The targets of the invention can further be described in terms of material composition, average grain size in particular regions and/or throughout the target, and/or texture. HCM targets produced in accordance with the invention can have an average grain size within a particular desired range. The desired range can be a grain size range where grain size uniformity and stability is maximized for a particular material and/or a particular HCM system. The particular grain size or range of grain sizes desired can also be based upon maximization of target life, particle performance and/or uniformity of target wear which can in turn affect film quality and uniformity. In general, HCM targets of the invention will fall into two category descriptions. The first category is sub-micron grain size targets where the average grain size of the target material is less than 1 micron. The second target category includes targets having a grain size of from greater than or equal to 1 micron. For copper-comprising materials, targets in the second category can typically have average grains sizes of less than or equal to about 20 microns. For Ti or Ta materials, targets in the second category can have an average grain size of up to 30 microns. For aluminum comprising materials, targets in the second category can have average grain sizes of less than 150 micron.

Both categories of targets can be produced to have an overall grain size standard deviation of less than 15% (1-σ) throughout specific areas of the target (base, radius or sidewall) and in general, methodology of the invention an produce targets having an overall grain size standard deviation of 15% (1-σ) throughout the entire target. Although the average grain size of target materials of the invention will vary based upon the particular material (and primarily based upon the base metal), the grain size uniformity (standard deviation) can be achieved for each of the types of materials discussed above. In particular instances, the targets of the invention will have an overall standard deviation throughout the target of less than or equal to 10% (1-σ), and in particular embodiments less than 6% (1-σ).

Methodology for production of HCM targets in accordance with the invention generally utilizes a first process where a high-purity metal, alloy or doped metallic material is processed utilizing equal channel angular extrusion and/or cryogenic forming to produce a material having either a sub-micron grain size or a grain size of from 1 to less than 20 microns (where grain size refers to the average grain size of the material). The material subsequently undergoes cold forming to produce an HCM (or alternative three-dimensional shape) configuration. The cold forming can comprise one or more processes including deep drawing, explosive forming, hot-blow forming, cold forging, spin forming, hydroforming, superplastic forming and other appropriate shape-forming processes. In particular embodiments, the cold forming preferably comprises deep drawing.

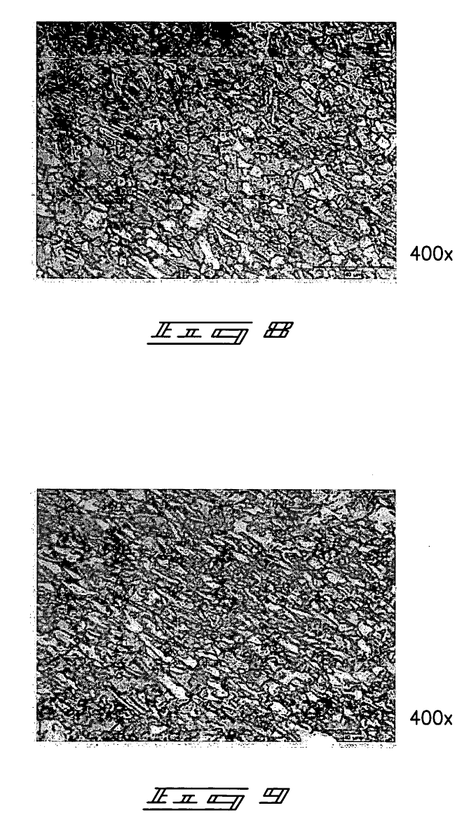

Referring to FIG. 6, such illustrates an exemplary equal channel angular extrusion (ECAE) device 50. Device 50 comprises a mold assembly 52 that defines a pair of intersecting channels 54 and 56. Intersecting channels 54 and 56 are identical or least substantially identical in cross-section, with the term “substantially identical” indicating that the channels are identical with an acceptable tolerance of an ECAE apparatus. In operation, a billet 58 (which can be any of the materials described above) is extruded through channels 54 and 56. Such extrusion results in plastic deformation of the billet by simple shear, layer after layer, in a thin zone located at the crossing plane of the channels. Although it can be preferable that channels 54 and 56 intersect at an angle of about 90°, it is to be understood that an alternative tool can be utilized (not shown). A tool angle (channel intersect angle) of about 90° can be preferable since an optimal deformation (true shear strain) can be attained.

ECAE can introduce severe plastic deformation in the extruded material while leaving the dimension of the block of material unchanged. ECAE can be a preferred method for introducing severe strain in a metallic material in that ECAE can be utilized at low loads and pressures to induce strictly uniform and homogenous strain. Additionally, ECAE can achieve a high deformation per pass (true strain ε=1.17); can achieve high accumulated strains with multiple passes through an ECAE device (at n=4 passes ε=4.64); and can be utilized to create various textures/microstructures within materials by utilizing different deformation routes (i.e. by changing an orientation of the material block between passes through an ECAE device).

In an exemplary method of the present invention, ECAE is conducted at a strain rate and processing temperature sufficient to obtain desired microstructures (for example a weak texture and small grain size) within a billet or block of a particular material, and to generate a uniform stress-strain state throughout the material. The material can be passed through an ECAE apparatus one, more than one, or several times and with numerous routes at a temperature which can correspond to cold or hot processing of the material. For particular materials, a preferred route to utilize with multiple passes through an ECAE apparatus can be the “route D”, which corresponds to a constant 90 billet rotation before each successive pass. Since the ECAE route can affect structural orientation produced during dynamic recrystallization, one or more particular routes can be chosen for deformation passes to induce a desired orientation in the particular material processed.

In particular applications, the ECAE processed block will have undergone at least 1 ECAE pass. Typically, ECAE processing can comprise from 4-8 passes and can preferably comprise from 4-6 passes. Such exemplary number is generally found sufficient to promote grain refinement to a submicron size by mechanically induced dynamic recrystallization. Alternatively, a larger grain size in the range of from 1 micron to about 20 microns can be produced utilizing fewer ECAE passes and/or alternative extrusion routes.

ECAE processing can optionally comprise performing one or more heat treatment. Such heat treatment can comprise anneal heating between at least some of the extrusion passes, anneal heating after the extrusion, or both. As would be understood by one of ordinary skill in the art, an appropriate temperature of the various heat treatments performed during ECAE processing can vary and can be determined based upon the particular material being extruded.

In alternative processing, grain size refinement in accordance with the invention can utilize one or more cryogenic techniques such as cryogenic forging, cryogenic rolling, etc. Regardless of which grain refinement technique is utilized in accordance with the invention, a particular grain size can be produced to enhance grain size stability for a particular material being processed. In particular, a grain size is produced which can allow grain size stability during sputtering processing and/or exposure to other high temperature operations. Such grain size stability can allow consistent thin film quality and uniformity, uniform target wear and increased target life.

Once the desired grain size has been achieved in a particular material, the material can be formed into a HCM configuration (or alternative configuration) by cold working techniques. Such cold working can comprise for example, cold forging, spin forming and/or alternative cold forming operations. In particular instances cold working including deep drawing is utilized to form HCM target configurations. Studies conducted to determine the effect of deep drawing on grain size, mechanical and crystallographic texture (discussed more fully below) indicate that the pre-drawing grain size is maintained during deep drawing with little or no changes in mechanical and crystallographic texture.

Annealing studies were performed on post grain refinement processed materials in order to determine stability of grain size and texture for particular materials when exposed to temperatures simulating or exceeding target temperatures reached during sputtering processes. Such studies were performed on both pre-drawn and deep drawn materials to determine the effect of deep drawing on grain size and microstructure stability. These studies (described more fully below) indicate that for particular materials a grain size of between 1 and 20 microns is preferable to maximize grain size and microstructure stability while texture and grain size for alternative materials can be stable even when processed to have a sub-micron grain size. Accordingly, different grain size and texture can be preferred based on a composition of material and/or the temperature the target will be subjected to during sputtering events.

For particular materials, such as particular copper materials, a sub-micron grain size can be preferred. For other copper materials, an average grain size in the range of 1 micron to 20 micron can be preferred. For particular materials and applications it can be preferred that the average grain size of the HCM target is from 1 micron to 15 microns. For other materials a preferred average grain size is less than 15 microns and can more preferably be from 1 micron to about 10 microns. For alternative metal materials (e.g. Ti, Ta or Al materials), other grain sizes may be preferred.

One factor to be considered in determining a preferred grain size is the sputtering temperature at which a material is to be deposited. In general, a smaller grain size can be preferable for low temperature sputtering. Accordingly, where only low sputtering temperatures (less than 125° C. for certain copper materials, for example) a sub-micron structure can be stable and can therefore be preferred to maximize benefits on target life, target wear uniformity and uniformity and quality in resulting films.

The results of the studies described below indicate that methodology in accordance with the invention can be utilized to produce HCM sputtering targets and alternative three-dimensional target shapes having relatively small average grain size relative to conventional methods of forming three-dimensional targets. Accordingly, targets formed in accordance with the invention can comprise a shape configuration similar or identical to conventional targets while having improved target life uniformity and target wear and ability to provide improved deposited film uniformity and film quality.

Film deposition utilizing targets of the invention can be conducted utilizing conventional or yet to be developed sputtering systems. In general, film deposition methodology of the invention will include providing an HCM target or alternative three-dimensional target of the invention within a deposition chamber of an appropriate sputtering system, such as the HCM sputtering system illustrated in FIG. 5. A substrate is provided within the chamber and, utilizing high-density plasma, material is sputtered from the target to form a layer of material across the substrate.

The film formed utilizing copper-comprising targets of the invention are consistently of uniform thickness, having a thickness uniformity of less than or equal to 3% (1-σ). This uniformity is achieved even across large substrate surfaces, such as 300 mm wafers. As will be understood by those skilled in the art, deposition parameters can be adjusted to assist maximization of performance of a target of a particular material. High-uniformity films formed utilizing targets of the invention can be deposited to have a metallic composition and purity substantially identical to the target materials. Similar uniformity can be achieved for films formed from targets of alternative materials in accordance with the invention.

The following examples section reports studies and results for particular materials. It is to be understood that the particular materials are exemplary and that the examples are not intended to limit the scope of the invention.

### EXAMPLES

In one study, a composition comprising 6N copper (99.9999%, by weight) to which was added 1.7-1.9 ppm Ag was subjected to six passes of equal channel angular extrusion (route D) followed by 70% reduction by rolling, and annealing at 235° C. for 1 hour. The effects of deep drawing and annealing after deep drawing were investigated utilizing two independent pieces of the 10 micron ECAE silver-doped copper. A first piece had a diameter of from 8.5 inches, and a second piece had a diameter of about 9 inches. Each of the first and second pieces had a thickness of 0.375 inches prior to deep drawing.

Referring to FIG. 7, such illustrates the cross-section of an exemplary deep drawn target 12A which illustrates a top portion 60, a side portion 62 which surrounds hollow interior 19, and a radius portion 64 (disposed at the intersection between side portion 62 and top portion 60). Each of the two deep drawn targets was sampled along the top, side and radius portions to observe effects of deep drawing. Deep drawing of the 9 inch diameter piece produced a 1.05 inch longer wall length compared to the 8.5 inch diameter deep drawn sample with substantially similar wall thicknesses in each piece. The final wall thickness reduced the material thickness about 55% resulting in a wall thickness of 0.175 inches. The thickness of the top portion for each piece after deep drawing was approximately 0.350 inches.

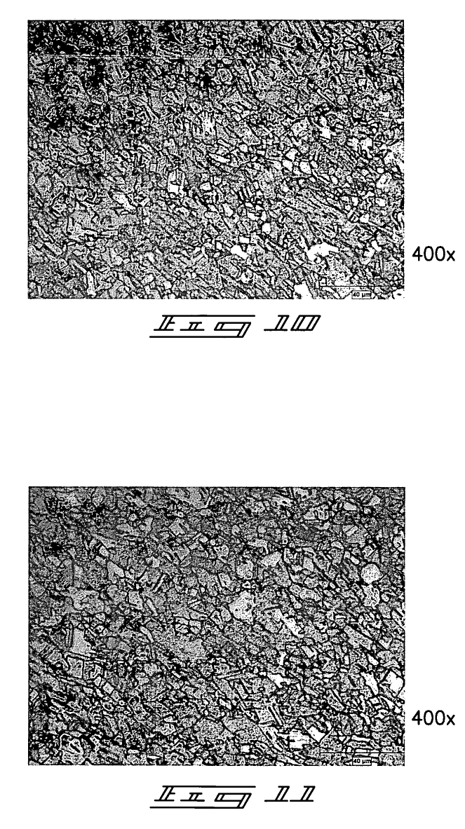

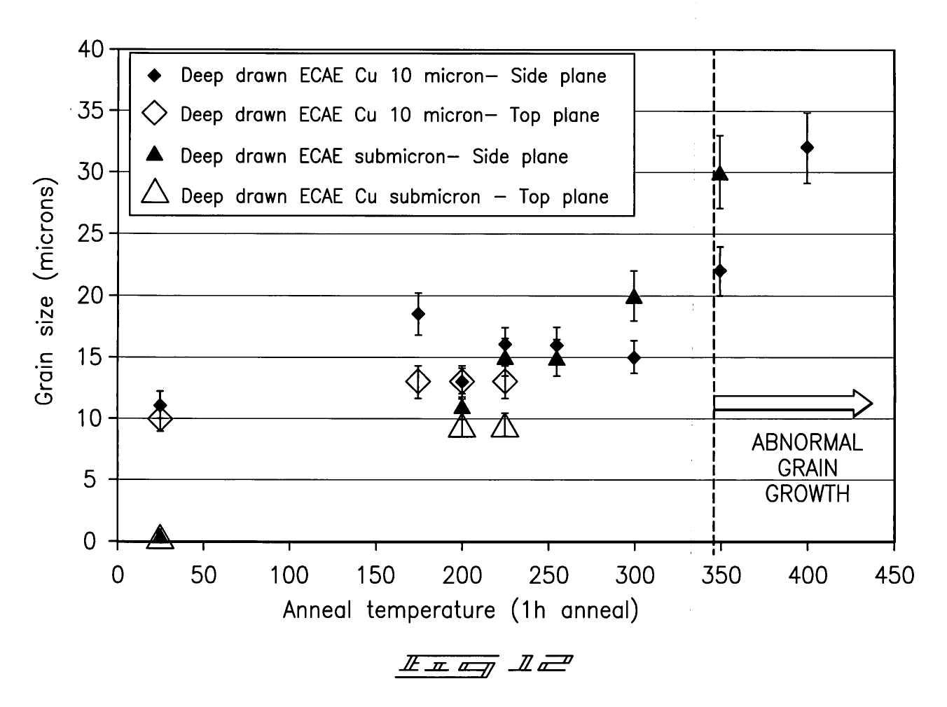

Microstructure of the deep drawn silver-doped copper resulting from the 9-inch piece is illustrated in FIGS. 8 and 9. Referring to FIG. 8, a 400× magnification of a top plane is shown revealing an equiaxed grain structure of average grain size of 7-10 microns. Referring to FIG. 9, a side planar portion is shown at 400× magnification revealing grain structures having an average diameter of 7-10 microns. The microstructure observed for the deep drawn 8-inch piece was similar (not shown).

Cross-sectional microstructure was also studied with cross-sections being taken along a top portion, side portion, radius portion near the top area, and radius portion toward the side area of the deep drawn material. Such studies revealed an average grain size of 6-10 microns along the top cross-section, grains having an average grain size of 2-10 along the side cross section, an average grain size of from 6-10 microns in the radius cross section near the top, and a 2-10 micron average grain size in the radius cross-section taken towards the side area (not shown).

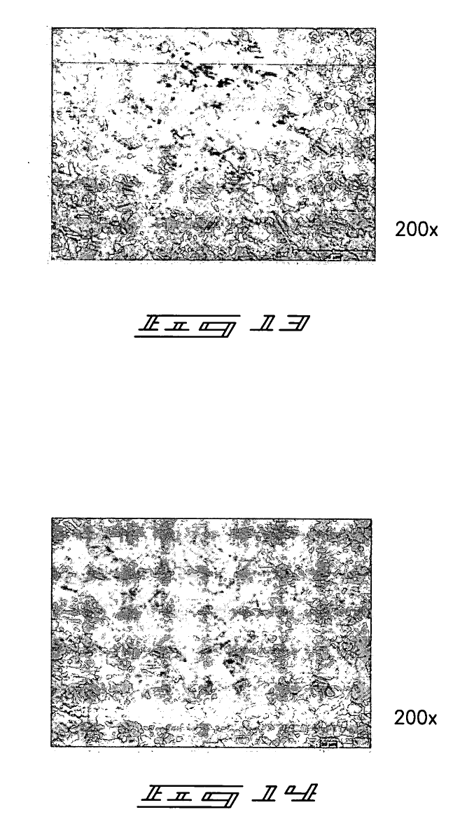

The deep drawn silver-doped copper material was subjected to annealing at 225° C. for 1 hour to determine the effects of annealing after deep drawing. A 400× magnification of a top cross-section of the target is shown in FIG. 10 and reveals an equiaxed grain structure with an average grain size of 6-8 microns. A cross-section along the side portion of the target reveals an average grain size of 8-10 microns with equiaxed grains as indicated by the 400× magnification shown in FIG. 11. The equiaxed grains within the side portions are likely due to some recrystallization during the anneal.

The above studies indicate that the 10 micron grain structure is stable after deep drawing and annealing at 225° C. for 1 hour. This results indicate that the 10 micron grain structure is stable for use for sputtering the Ag-doped copper material at a sputtering temperature of from about 100° C. to about 200° C.

In additional studies, equal channel angular extruded samples were prepared to produce particular grain sizes to study the stability of particular grain size during deep drawing and/or annealing processes. In a particular study, a high-purity (99.9999%) copper was utilized. A first sample was produced utilizing ECAE having a sub-micron grain size. A second sample of the 99.9999% (6N) copper material was produced (utilizing ECAE) to have a grain size of between 10 and 15 microns. For these test samples the extruded and rolled pieces had dimensions of 4.125 inches diameter and 0.125 inch thickness.

Each of the two pieces was deep drawn to final dimensions of 2.435 inches outer diameter and height of 1.5 inches with a sidewall thickness of 0.095 inches for a thickness reduction in the sidewall material of approximately 25%. The microstructure of each of the two pieces was characterized in various areas of the deep drawn target to assess the microstructure and grain stability. The analysis revealed that the 0.5 micron average grain size was retained in the first piece during deep drawing with retention in microstructure hardness and weak texture. Similarly, for the second piece, the 10 micron average grain size was maintained during deep drawing along with microstructure hardness and weak texture. A 5-10% increase in surface hardness was observed in the second piece (10 micron average grain size).

The two deep drawn pieces were subsequently annealed for 1 hour at various temperatures as presented in FIG. 12. Side planes and top planes of each of the deep drawn materials were analyzed post-anneal. The results presented in FIG. 12 indicate a full recrystallization of the deep drawn 6N copper material initially having a 0.5 micron grain size with full recrystallization occurring during a one hour of anneal at a temperature of >200° C. A similar grain size evolution was observed for the 10 micron sample when annealed for 1 hour at a temperature of from 200° C. through 350° C. Accordingly, ECAE copper maintains a fine grain structure of from 10-20 microns when annealed between 200° C. and 300° C., where the initial deep drawn microstructures have average grain size of either 0.5 or about 10 microns. Grain size differences were not observed between sidewalls and top walls of the annealed materials. Localized abnormal grains (greater than 50 microns) appear in materials after annealing 1 hour at 350° C. with the initial 10 micron structure appearing to be more resistant to rain growth that the corresponding sub-micron grain material.

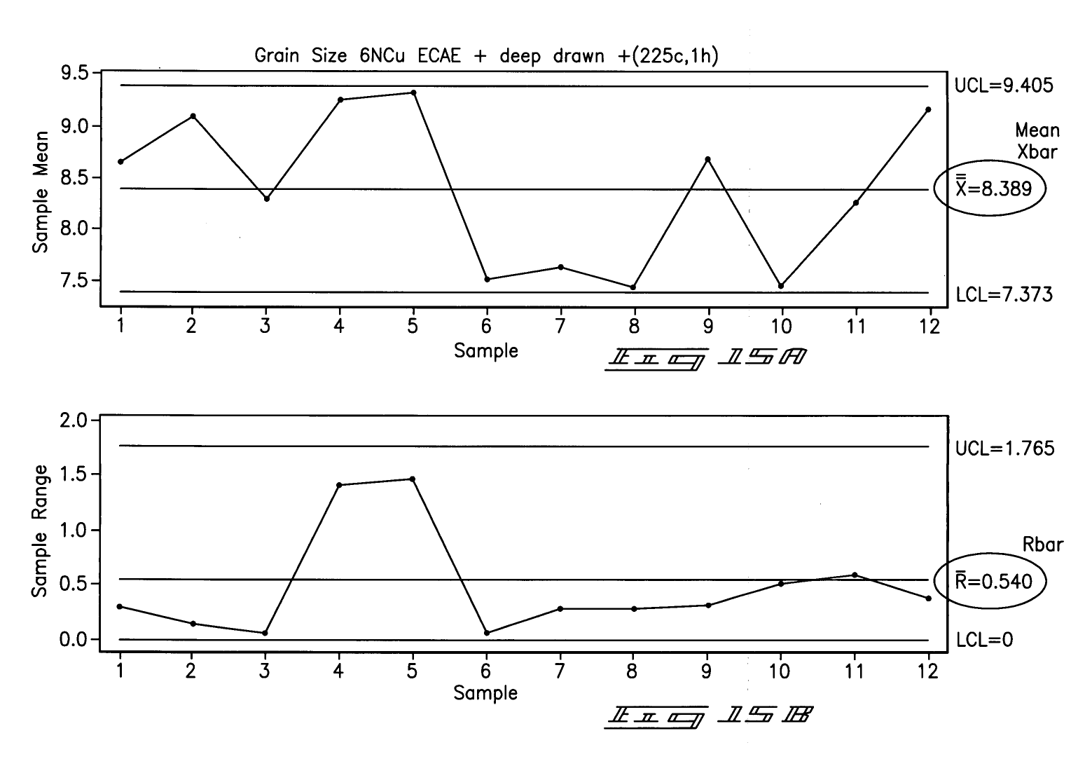

The resulting microstructures of post anneal materials are shown in FIGS. 13 and 14. Deep drawn material having a pre-anneal average grain size of 0.5 microns is shown in FIG. 13 after anneal at 300° C. for 1 hour. The 200× magnification of the sidewall of such material has an average grain size of from 18-20 microns.

The material having a 10 micron average grain size (pre-anneal) was, after deep drawing, annealed at 300° C. for 1 hour. A 200× magnification of the annealed material is shown in FIG. 14. Such shows the sidewall grain structure having an average grain size of about 15 microns.

Referring to Table 1, such shows the texture evolution upon annealing of deep drawn copper. having an average grain size of 0.5 microns pre-anneal. Table 1, Part A represents evolution for sidewall material which had a pre-anneal sub-micron average grain size. Table 1, Part B represents texture evolution for material from the top portion of the structure.

TABLE 1
Part A: Target sidewall texture evolution for 6N copper having
a pre-anneal sub-micron average grain size.

| 4 Poles | | | | | | | |
|---|---|---|---|---|---|---|---|
| Ratio | AD | 175° C. | 200° C. | 225° C. | 255° C. | 300° C. | 350° C. |
| 111 | 33% | 82% | 50% | 51% | 54% | 53% | 55% |
| 200 | 30% | 3% | 11% | 12% | 9% | 10% | 12% |
| 220 | 17% | 10% | 18% | 27% | 23% | 23% | 22% |
| 113 | 20% | 5% | 21% | 11% | 14% | 14% | 11% |

TABLE 1
Part B: Texture evolution in the top portion of a 6N copper target
having a pre-anneal sub-micron average grain size.

| Poles Ratio | AD | 175° C. | 200° C. | 225° C. |
|---|---|---|---|---|
| 111 | 2% | 16% | 12% | 4% |
| 200 | 35% | 43% | 60% | 31% |
| 220 | 49% | 29% | 13% | 55% |
| 113 | 14% | 12% | 15% | 10% |

Table 1 reports textures after deep drawing in the as-deformed (AD) condition, and for annealing for 1 hour at the indicated temperature. As determined by the results in Part A, the weak initial texture evolves to a weak (111) type texture in the sidewall after anneal for 1 hour at 200° C. Anneal between 200° C. and 350° C. results in stable texture. The strong texture observed at 175° C. corresponds to the transition case of partial recrystallization.

Referring to Table 1, Part B, with respect to the top wall the initial weak (200)/(220) texture remains relatively stable up to 225° C. anneal for 1 hour. The texture orientation between the top and sidewalls varies due to difference in deformation mode and level. The results indicate that overall the texture strength remains weak with texture stability observed after 200-350° C. anneals for 1 hour.

Texture evolution for 10 micron (average grain size pre-anneal) copper material is present in Table 2, Parts A (sidewall) and Part B (top wall).

TABLE 2
Part A: Target sidewall texture evolution for copper having a pre-
anneal average grain size of 10 microns.

| 4 Poles | | | | | | | |
|---|---|---|---|---|---|---|---|
| Ratio | AD | 750° C. | 200° C. | 225° C. | 255° C. | 300° C. | 350° C. |
| 111 | 38% | 24% | 33% | 24% | 27% | 29% | 18% |
| 200 | 30% | 28% | 23% | 21% | 19% | 30% | 24% |
| 220 | 19% | 39% | 21% | 30% | 31% | 20% | 30% |
| 113 | 13% | 9% | 23% | 25% | 23% | 21% | 28% |

TABLE 2
Part B: Texture evolution in the top portion of a copper
target having pre-anneal average grain size of 10 microns.

| 4 Poles Ratio | AD | 175° C. | 200° C. | 225° C. |
|---|---|---|---|---|
| 111 | 14% | 12% | 17% | 17% |
| 200 | 43% | 39% | 43% | 30% |
| 220 | 32% | 32% | 26% | 40% |
| 113 | 11% | 17% | 14% | 13% |

The texture evolution results indicate that for the sidewall portion the texture remains weak and close to random for anneal up to 350° C. with an almost equal percent ratio for each of the four present poles. The top wall results presented in Part B indicate that the initial weak (200)/(220) texture remains stable for anneal up to 225° C. The texture orientation between the top and sidewall varies due to the difference in the deformation mode and level. The difference is smaller for the initial 10 micron average grain size sample versus initial 0.5 micron average grain size sample. The overall texture strength remains weak in each sample. The 4-pole ratio of the copper having 10 micron average grain size (pre-anneal) is relatively stable with annealing for 1 hour up to 350° C.

These results further indicate that copper having 10 micron average grain size is more stable for deep drawn structures exposed to temperatures from 225° C. to about 300° C. ECAE material having an average grain size of 0.5 microns recrystallizes at about 200° C. to result in a 10 micron grain structure. Target temperatures during sputtering of this type of copper materials are typically over 100° C. for several hours indicating that the 10 micron structure can be preferred due to relatively high thermal stability.

The uniformity of grain size in material processed in accordance with the invention was evaluated. For a particular exemplary study, a copper material comprising high purity copper (6N) doped with silver (approximately 1.9 ppm) was utilized. Processing included ECAE followed by 70% (reduction) rolling and annealing at 250° C. for 1 hour. The resulting target blank (9-inch diameter×0.357-inch thickness) had an average grain size of 10 microns. The blank was deep drawn and subsequently annealed at 225° C. for 1 hour. Twelve target locations were analyzed, indicated as locations A-L on FIG. 7. Two fields were measured at each location using CLEMEX® software (Les Technologies Clemex Inc./Clemex Technologies Inc. Quebec Canada) to calculate grain size. The measurements for each field and averages are presented in Table 3.

TABLE 3
Grain sizes at 12 target locations for a Cu/Ag deep drawn and
annealed target.

| | Grain size (microns) | | |
|---|---|---|---|
| Target location | Field 1 | Field 2 | Average of two fields |
| A | 8.8 | 8.5 | 8.65 |
| B | 9.16 | 9.02 | 9.09 |
| C | 8.26 | 8.32 | 8.29 |
| D | 8.54 | 9.96 | 9.25 |
| E | 8.6 | 10.06 | 9.33 |
| F | 7.48 | 7.54 | 7.51 |
| G | 7.76 | 7.48 | 7.62 |
| H | 7.28 | 7.56 | 7.42 |
| I | 8.51 | 8.82 | 8.665 |
| J | 7.18 | 7.7 | 7.44 |
| K | 8.54 | 7.95 | 8.245 |
| L | 9.35 | 8.97 | 9.16 |
| Average (μm) | 8.288 | 8.490 | 8.389 |
| Minimum (μm) | 7.18 | 7.48 | 7.42 |
| maximum (μm) | 9.35 | 10.06 | 9.33 |

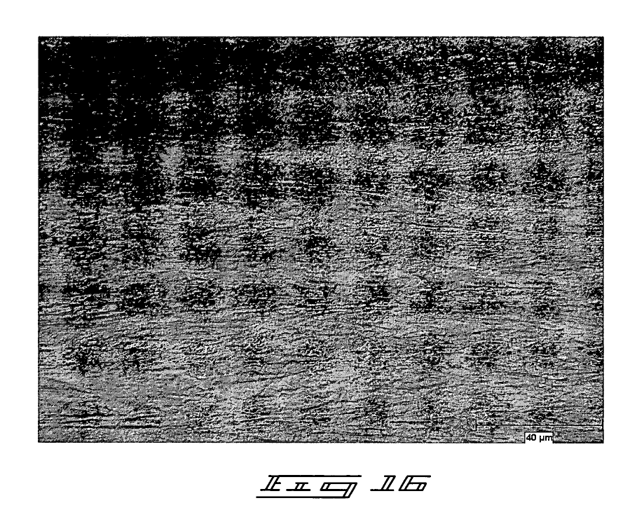

The grain size data presented in Table 3 was utilized to determine grain size uniformity of the target. The mean (Xbar) and the mean of range (Rbar) values are presented in FIG. 15. As shown, the mean (Xbar) value of 8.389 microns was determined, and the mean of range (Rbar) value was 0.540 microns. The estimated standard deviation (1-σ)=(Rbar)/d2=0.54/1.128=0.478, (i.e. 5.6% of the mean grain size Xbar, indicating a grain size uniformity of 5.6% (1-σ). In the equation for estimated standard deviation above, d2 is a statistical value for estimating the standard deviation based upon the Rbar. Where two measurements are performed per location (subgroup size =2), d2 is equal to 1.128.

Additional studies were performed utilizing an aluminum alloy containing aluminum and 0.5% copper (Al0.5Cu). A first and a second sample of the aluminum alloy were subjected to 6 passes of ECAE, route D. The ECAE deformed samples had an average grain size of 0.5 micron. The second sample was subsequently annealed at 150° C. for one hour, and retained an average grain size of 0.5 micron. The first sample (in as deformed condition) and the second sample (post-anneal) were each subjected to deep drawing. Macro-etching of the deep drawn structures (not shown) revealed intersecting macro-shear bands indicative of submicron structure.

Although the resulting grain size was too small in both the first and second samples to be accurately determined via optical microscopy, optical microscopy does verify the presence of visible flow lines which are typical for and indicative of submicron ECAE aluminum. An exemplary optical micrograph showing flow lines after the above described processing and deep drawing of Al0.5Cu material is shown in FIG. 16. These results indicate the submicron structure produced by ECAE in the aluminum alloy material is stable after deep drawing.

In general, the results of the microstructure and grain size studies for the copper materials above and additionally analyzed materials indicates that for particular materials sub-micron grain size can be preferred where the said micron grain size is stable at or near the sputtering temperature typically utilized for sputtering such material. In particular instances, a sub-micron average grain size can preferably be from 0.2 microns to less than 1.0 microns. However, for materials where a grain size of from 1-20 microns provides increased thermal stability relative to submicron grains, an average grain size in the 1-20 micron range can be preferred. Methodology in accordance with the invention allows particular grain size to be achieved for a particular material and for a particular sputtering temperature.

Targets in accordance with the invention can advantageously be produced to increase or maximize target life, to provide improved uniformity of target wear, improved uniformity of resulting deposited thin films, and consistent quality in the resulting films. Preferred grain sizes for targets of the invention based upon the composition of the target material were determined for a number of materials. For high purity copper targets, an average grain size of less than 30 microns is preferred, with an average grain size of from about 5 microns to about 20 microns being more preferred. For copper alloy targets, the average grain size is preferably less than 30 microns in all cases, with a grain size of from 5-20 microns being more preferred for particular alloys and a submicron grain size being preferred for other copper alloys. For doped copper materials, the preferred grain size is less than 30 microns, and more preferably from about 5 to about 20 microns.

Where targets of the invention comprise high purity aluminum or doped aluminum, targets preferably have an average grain size of from about 10 microns to less than 150 microns and more preferably less than 100 microns. For aluminum alloys, a preferred grain size is from 0.2 microns to less than 30 microns, with a submicron grain size being more preferred.

For titanium alloys and tantalum alloys, a preferred average grain size is less than 30 microns, with a more preferred grain size being from about 5 to about 20 microns for particular alloys, and a submicron grain size being preferred for others. For doped-titanium and doped-tantalum materials, a preferred average grain size is less than 30 microns, with a more preferred average grain size being from about 5 to about 20 microns for particular alloys, and a submicron (typically from 0.2 to less than 1 microns) average grain size being preferred for others.

Thin films produced by sputtering utilizing targets in accordance with the invention having target grain sizes in the preferred ranges set forth above, can consistently be formed to have a uniformity of less than or equal to 3% (1σ) across the surface of a semiconductor wafer.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

The invention claimed is:

1. A three-dimensional sputtering target comprising a copper-comprising material having an average grain size throughout the target of from about 0.2 micron to about 30 micron.

2. The three-dimensional target of claim 1 wherein the target is a hollow cathode magnetron sputtering target.

3. The target of claim 1 wherein the target has a grain size uniformity throughout the target of less than or equal to 15% (1-σ).

4. The target of claim 1 wherein the target has a grain size uniformity throughout the target of less than or equal to 10% (1-σ).

5. The target of claim 1 wherein the target has a grain size uniformity throughout the target of less than or equal to 6% (1-σ).

6. The target of claim 1 wherein the average grain size is less than one micron.

7. The target of claim 1 wherein the average grain size is from one micron to about 20 microns.

8. The target of claim 1 wherein the copper material has a copper content of at least 99.999%, by weight.

9. The target of claim 1 wherein the copper material has a copper content of at least 99.9999%, by weight.

10. The target of claim 1 wherein copper-comprising material contains at least one element selected from the group consisting of Cd, Ca, Au, Ag, Be, Li, Mg, Al, Pd, Hg, Ni, In, Zn, B, Ga, Mn, Sn, Ge, W, Cr, O, Sb, Ir, P, As, Co, Te, Fe, S, Ti, Zr, Sc, Si, Pt, Nb, Re, Mo, and Hf.

11. The target of claim 10 wherein the target contains a total amount of the at least one element of from 1 ppm to 100 ppm, by weight.

12. A three-dimensional sputtering target comprising a metallic material comprising at least one member selected from the group consisting of Cu, Ti, and Ta, the target having an average grain size throughout the target of from about 0.2 micron to about 30 micron and a grain size standard deviation of less than 15% (1-σ).

13. The target of claim 12 wherein the grain size standard deviation is less than or equal to 10% (1-σ).

14. The target of claim 12 wherein the grain size standard deviation is less than or equal to 6% (1-σ).

15. The target of claim 12 wherein the metallic material is an alloy.

16. The target of claim 12 wherein the metallic material contains at least one dopant element and has a total dopant concentration of from 1 ppm to 100 ppm.

17. A three-dimensional sputtering target comprising an aluminum-comprising material having an average grain size throughout the target of from 0.2 microns to less than 150 microns, and having a grain size standard deviation throughout the target of less than 15% (1-σ).

18. The target of claim 17 wherein the aluminum-comprising material is an aluminum alloy and has and average grain size of from 0.2 microns to about 30 microns.

19. The target of claim 17 wherein the aluminum-comprising material is doped aluminum and has and average grain size of from 10 microns to about 150 microns.

20. The target of claim 17 wherein the aluminum-comprising material contains at least one element selected from the group consisting of Cu, Cd, Ca, Au, Ag, Be, Li, Mg, Pd, Hg, Ni, In, Zn, B, Ga, Mn, Sn, Ge, W, Cr, O, Sb, Ir, P, As, Co, Te, Fe, S, Ti, Zr, Sc, Si, Pt, Nb, Re, Mo, and Hf.

21. The target of claim 20 wherein the aluminum-comprising material contains a total amount of the at least one element of from 1 ppm to 100 ppm, by weight.

22. A method of forming a hollow cathode magnetron sputtering target, comprising:
providing a metallic material having an average grain size of less than or equal to about 30 microns; and
subjecting the metallic material to forming utilizing a forming process selected from the group consisting of deep drawing, cold forging, explosive forming, spin forming, hot blow forming, and hydroforming.

23. The method of claim 22 wherein providing the metallic material comprises producing the grain size utilizing at least one of cryogenic forming and equal channel angular extrusion.

24. The method of claim 23 wherein the method comprising at least one pass of equal channel angular extrusion.

25. The method of claim 22 wherein the average grain size is less than one micron.

26. The method of claim 22 wherein the average grain size is from one micron to about 20 microns.

27. The method of claim 22 wherein the metallic material comprises at least one element selected from the group consisting of Cu, Al, Ti and Ta.
